(19) United States
(12) Patent Application Publication
(10) Pub. No.: US 2023/0354662 A1
(43) Pub. Date: Nov. 2, 2023

(54) DISPLAY DEVICE

(71) Applicant: Samsung Display Co., LTD., Yongin-si (KR)

(72) Inventor: CHUNGI YOU, Asan-si (KR)

(73) Assignee: Samsung Display Co., LTD., Yongin-si (KR)

(21) Appl. No.: 18/302,064

(22) Filed: Apr. 18, 2023

(30) Foreign Application Priority Data
Apr. 27, 2022 (KR) 10-2022-0052199

(51) Int. Cl. H10K 59/124; H10K 59/131

(52) U.S. Cl. CPC H10K 59/131; H10K 59/124

(57) ABSTRACT

A display device includes a display region, a first wire region, a second wire region, and a peripheral region; a pixel structure disposed on a substrate; a first wire part disposed on the substrate in the first wire region, and including first wires electrically connected to the pixel structure; an inorganic insulating layer covering the first wire part; a second wire part disposed on the inorganic insulating layer in the second wire region, and including second wires electrically contacting the first wires through first through-holes formed through the inorganic insulating layer and arranged along a boundary between the first wire region and the second wire region, respectively; an organic insulating layer covering the second wire part; and a protective layer disposed on the organic insulating layer, and at least partially overlapping the first through-holes in a plan view.

### CROSS-REFERENCE TO RELATED APPLICATION

This application claims priority to and benefits of Korean Patent Application No. 10-2022-0052199 under 35 U.S.C. § 119, filed on Apr. 27, 2022, in the Korean Intellectual Property Office (KIPO), the entire disclosure of which is incorporated herein by reference.

### BACKGROUND

### 1. Technical Field

Embodiments of the disclosure relate to a display device.

### 2. Description of the Related Art

A display device may include a display region in which an image is displayed, and a non-display region in which an image is not displayed and surrounding the display region. A pixel structure configured to emit light and wires configured to transmit an electrical signal to the pixel structure may be disposed in the display region. Some of the wires may extend from the display region to the non-display region so as to be disposed in the non-display region and electrically connected to a driving member configured to provide the electrical signal.

As an area occupied by some of the wires in the non-display region increases, an area of a bezel of the display device may be increased. In addition, some of the wires disposed in the non-display region may be damaged by moisture, a gas, and the like.

### SUMMARY

One object of the disclosure is to provide a display device including a bezel having a relatively small area.

Another object of the disclosure is to provide a display device capable of preventing a wire from being damaged.

However, objects of the disclosure are not limited to the above-described objects, and may be variously expanded without departing from the idea and scope of the disclosure.

In order to achieve the above objects of the disclosure, according embodiments of the disclosure, a display device includes a display region; a first wire region extending in a direction from a side of the display region; a second wire region extending in the direction from the first wire region; a peripheral region surrounding the display region, the first wire region, and the second wire region; a pixel structure disposed on a substrate in the display region; a first wire part disposed on the substrate in the first wire region, and including first wires electrically connected to the pixel structure; an inorganic insulating layer covering the first wire part; a second wire part disposed on the inorganic insulating layer in the second wire region, and including second wires electrically contacting the first wires through first through-holes formed through the inorganic insulating layer and arranged along a boundary between the first wire region and the second wire region, respectively; an organic insulating layer covering the second wire part; and a protective layer disposed on the organic insulating layer, and at least partially overlapping the first through-holes in a plan view.

According to an embodiment, the display device may further include a sealing region defined by a sealing opening that penetrates the organic insulating layer, and surrounding the display region.

According to an embodiment, the second wire region may be spaced apart from the sealing region in a plan view, and a portion of the first wire region may overlap a portion of the sealing region in a plan view.

According to an embodiment, the protective layer may cover a portion of a top surface of the inorganic insulating layer exposed by the sealing opening in a region where the portion of the first wire region overlaps the portion of the sealing region in a plan view.

According to an embodiment, the protective layer may further cover the sealing opening and the entire top surface of the inorganic insulating layer exposed by the sealing opening in the region where the portion of the first wire region overlaps the portion of the sealing region in a plan view.

According to an embodiment, the display device may further include a sealing member disposed within the sealing opening; and a cover member supported by the sealing member.

According to an embodiment, the pixel structure may include a semiconductor layer disposed on the substrate; a gate electrode disposed on the semiconductor layer and at least partially overlapping a portion of the semiconductor layer in a plan view, the gate electrode and the first wire part including a same material; the inorganic insulating layer covering the gate electrode; a source-drain electrode disposed on the inorganic insulating layer and electrically contacting another portion of the semiconductor layer, the source-drain electrode and the second wire including a same material; the organic insulating layer covering the source-drain electrode; and a pixel electrode layer disposed on the organic insulating layer and electrically contacting the source-drain electrode, the pixel electrode layer and the protective layer including a same material.

According to an embodiment, the first wire part may include a material having a first resistivity, and the second wire part may include a material having a second resistivity that is lower than the first resistivity.

According to an embodiment, the display device may further include a first power supply electrode layer disposed on the substrate and adjacent to the side of the display region, and receiving a first power supply voltage; and a second power supply electrode layer disposed on the substrate in the peripheral region, and receiving a second power supply voltage.

According to an embodiment, the first power supply electrode layer and the protective layer may include a same material.

According to an embodiment, the first power supply electrode layer may be electrically insulated from the protective layer.

According to an embodiment, the protective layer may be electrically connected to the second power supply electrode layer.

In order to achieve the above objects of the disclosure, according embodiments of the disclosure, a display device includes a display region, a first wire region extending from a side of the display region, a second wire region extending from the first wire region, and a peripheral region surrounding the display region, the first wire region, and the second wire region, and including a pad region in which pad electrodes are disposed; a pixel structure disposed on a substrate in the display region; a first wire part disposed on the substrate in the first wire region, and including first wires electrically connected to the pixel structure; an inorganic insulating layer covering the first wire part; a second wire part disposed on the inorganic insulating layer in the second wire region, and including second wires electrically contacting the first wires through first through-holes formed through the inorganic insulating layer and arranged along a boundary between the first wire region and the second wire region, respectively; an organic insulating layer covering the second wire part; and a first power supply electrode layer disposed on the organic insulating layer, electrically connected to at least one of the pad electrodes, and at least partially overlapping the first through-hole in a plan view.

According to an embodiment, the display device may further include a sealing region defined by a sealing opening that penetrates the organic insulating layer, and surrounding the display region.

According to an embodiment, the second wire region may be spaced apart from the sealing region in a plan view, and a portion of the first wire region may overlap a portion of the sealing region in a plan view.

According to an embodiment, the first power supply electrode layer may cover the sealing opening and an entire top surface of the inorganic insulating layer exposed by the sealing opening in a region where the portion of the first wire region overlaps the portion of the sealing region in a plan view.

According to an embodiment, the display device may further include: a sealing member disposed within the sealing opening; and a cover member supported by the sealing member.

According to an embodiment, the pixel structure may include a semiconductor layer disposed on the substrate; a gate electrode disposed on the semiconductor layer and at least partially overlapping one portion of the semiconductor layer in a plan view, the gate electrode and the first wire part including a same material; the inorganic insulating layer covering the gate electrode; a source-drain electrode disposed on the inorganic insulating layer and electrically contacting another portion of the semiconductor layer, the source-drain electrode and the second wire part including a same material; the organic insulating layer covering the source-drain electrode; and a pixel electrode layer disposed on the organic insulating layer and electrically contacting the source-drain electrode, the pixel electrode layer and the first power supply electrode layer including a same material.

According to an embodiment, the first wire part may include a material having a first resistivity, and the second wire part may include a material having a second resistivity that is lower than the first resistivity.

According to an embodiment, the display device may further include a second power supply electrode layer disposed on the substrate in the peripheral region. The first power supply electrode layer may receive a first power supply voltage, and the second power supply electrode layer may receive a second power supply voltage.

According to the embodiments of the disclosure, the display device may include a first wire part including first wires disposed on a substrate in a first wire region; an inorganic insulating layer covering the first wire part; second wires disposed on the inorganic insulating layer in a second wire region, and electrically contacting the first wires through first through-holes formed through the inorganic insulating layer and arranged along a boundary between the first wire region and the second wire region, respectively. Since the first wires make electrical contact with the second wires, wire widths of the first wires and the second wires can be relatively reduced, so that an area of a bezel of the display device can be relatively reduced.

According to the embodiments of the disclosure, the display device may include a second wire part, and a protective layer at least partially overlapping the first through-hole, so that the protective layer can prevent the first wire part and the second wire part, which are adjacent to the first through-hole, from being damaged.

According to the embodiments of the disclosure, the display device may include a second wire part, and a first power supply electrode layer at least partially overlapping the first through-hole, so that the first power supply electrode layer can prevent the first wire unit and the second wire part, which are adjacent to the first through-hole, from being damaged.

However, effects of the disclosure are not limited to the above-described effects, and may be variously expanded without departing from the idea and scope of the disclosure.

### BRIEF DESCRIPTION OF THE DRAWINGS

FIG. 1 is a schematic plan view illustrating a display device according to an embodiment of the disclosure.

FIG. 2 is a schematic sectional view illustrating a pixel structure included in the display device of FIG. 1.

FIG. 3 is a schematic enlarged plan view illustrating a region A of FIG. 1.

FIG. 4 is a schematic sectional view taken along line I-I′ of FIG. 3.

FIG. 5 is a schematic plan view illustrating a display device according to another embodiment of the disclosure.

FIG. 6 is a schematic enlarged plan view showing region B of FIG. 5.

FIG. 7 is a schematic sectional view taken along line II-II′ of FIG. 6.

FIG. 8 is a schematic plan view illustrating a display device according to still another embodiment of the disclosure.

FIG. 9 is a schematic enlarged plan view illustrating a region C of FIG. 8.

FIG. 10 is a sectional view taken along line III-III’ of FIG. 9.

### DETAILED DESCRIPTION OF THE EMBODIMENTS

Hereinafter, a display device according to embodiments of the disclosure will be described in more detail with reference to the accompanying drawings. The same or similar reference numerals will be used for the same components in the accompanying drawings.

Spatially relative terms, such as “beneath,” “below,” “under,” “lower,” “on,” “above” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein should be interpreted accordingly.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements.

If a first object “overlaps” a second object, at least part of the first object may face at least part of the second object in a direction or view.

The term “and/or” includes all combinations of one or more of which associated configurations may define. For example, “A and/or B” may be understood to mean “A, B, or A and B.”

For the purposes of this disclosure, the phrase “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z.

Unless otherwise defined or implied herein, all terms (including technical and scientific terms) used herein have the same meaning as commonly understood by those skilled in the art to which this disclosure pertains. It will be further understood that terms, such as those defined in commonly used dictionaries, should be interpreted as having a meaning that is consistent with their meaning in the context of the relevant art and the disclosure, and should not be interpreted in an ideal or excessively formal sense unless clearly so defined herein.

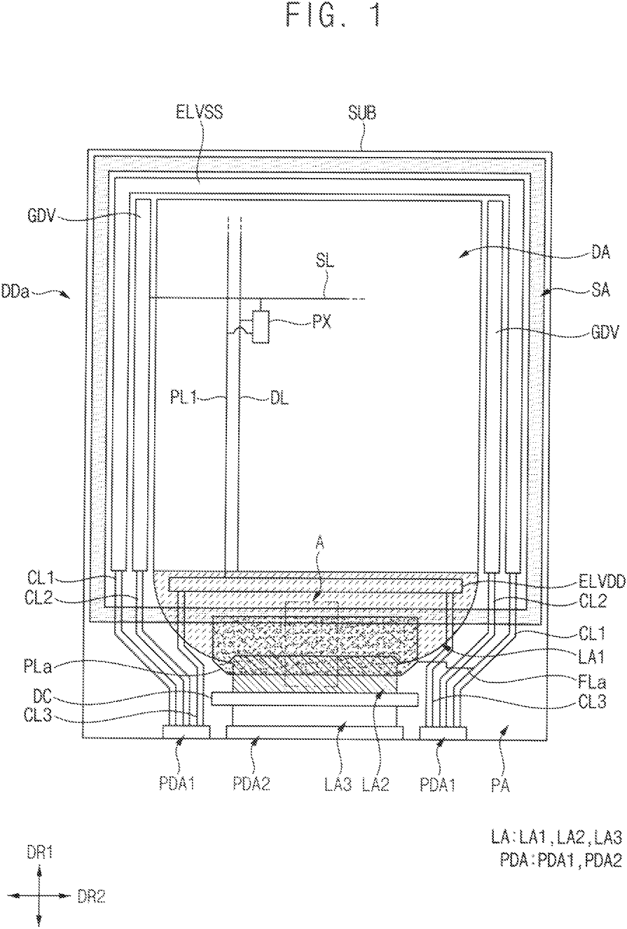

FIG. 1 is a schematic plan view illustrating a display device according to an embodiment of the disclosure.

Referring to FIG. 1, according to an embodiment of the disclosure, a display device DDa may include a substrate SUB, a pixel structure PX, and a protective layer PLa. The substrate SUB (and/or the display device DDa) may include a display region DA, a wire region LA, and a peripheral region PA. The peripheral region PA may include a pad region PDA.

The pixel structure PX and wires electrically connected to the pixel structure PX may be disposed in the display region DA. According to an embodiment, the wires may include a data line DL, a first power supply voltage line PL1, and a scan line SL.

The pixel structure PX may receive an electrical signal to emit light having a luminance corresponding to an intensity of the electrical signal. Each of the data line DL, the first power supply voltage line PL1, and the scan line SL may transmit the electrical signal to the pixel structure PX. For example, the data line DL may transmit a data signal to the pixel structure PX, the scan line SL may transmit a scan signal to the pixel structure PX, and the first power supply voltage line PL1 may transmit a first power supply voltage to the pixel structure PX.

Although FIG. 1 illustrates one pixel structure PX, one data line DL, one first power supply voltage line PL1, and one scan line SL for convenience of description, multiple pixel structures, and multiple data lines, multiple first power supply voltage lines, and multiple scan lines, which are electrically connected to the pixel structures, may be disposed in the display region DA.

The pad region PDA may be located on a lower portion of the substrate SUB. Pad electrodes may be disposed in the pad region PDA. Although not shown in FIG. 1, the pad electrodes may be electrically coupled (or electrically connected) to a flexible circuit film and the like.

In some embodiments, the pad region PDA may include a first pad region PDA1 in which first pad electrodes are disposed and a second pad region PDA2 in which second pad electrodes are disposed. An area of each of the first pad electrodes may be greater than an area of each of the second pad electrodes in a plan view, and a number of the second pad electrodes may be greater than a number of the first pad electrodes. However, the embodiments are not limited thereto.

The wire region LA may extend in the first direction DR1 from a side of the display region DA. The wire region LA may be defined as a region in which the wires disposed in the display region DA extend so as to be disposed outside the display region DA, or a region in which wires electrically contacting the wires disposed in the display region DA are disposed outside the display region DA.

According to an embodiment, the wire region LA may include a first wire region LA1, a second wire region LA2, and a third wire region LA3.

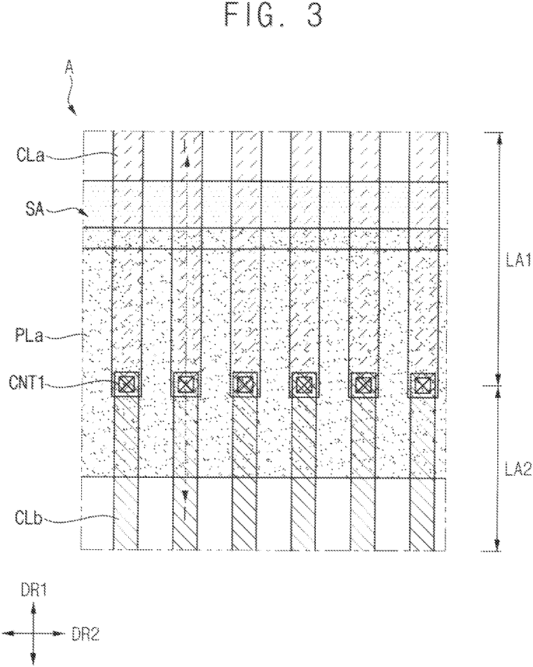

The first wire region LA1 may extend in the first direction DR1 from the side of the display region DA. Wires (e.g., CLa of FIG. 3) may be disposed in the first wire region LA1. According to an embodiment, the wires disposed in the first wire region LA1 may electrically contact the data line DL. As another example, according to another embodiment, the wires disposed in the first wire region LA1 may be an extension part in which the data line DL disposed in the display region DA extends outside the display region DA.

The second wire region LA2 may extend in the first direction DR1 from the first wire region LA1. Wires (e.g., CLb of FIG. 3) may be disposed in the second wire region LA2, and the wires disposed in the second wire region LA2 may electrically contact the wires disposed in the first wire region LA1 and a driving chip DC disposed in the peripheral region PA.

The third wire region LA3 may extend from the driving chip DC in the first direction DR1. Wires may be disposed in the third wire region LA3, and the wires disposed in the third wire region LA3 may electrically contact the driving chip DC and the second pad electrodes disposed in the second pad region PDA2.

The peripheral region PA may surround the display region DA and the wire region LA. Driving members configured to drive the display device DDa may be disposed in the peripheral region PA. For example, a first power supply electrode layer ELVDD, a second power supply electrode layer ELVSS, a gate driving member GDV, and the driving chip DC may be disposed in the peripheral region PA.

The first power supply electrode layer ELVDD may be adjacent to the side of the display region DA. The first power supply electrode layer ELVDD may be electrically connected to the first power supply voltage line PL1, and may provide the first power supply voltage to the first power supply voltage line PL1. According to an embodiment, the first power supply electrode layer ELVDD may be electrically connected to some of the first pad electrodes disposed in the first pad region PDA1 through a third connection line CL3.

The second power supply electrode layer ELVSS may be disposed at a periphery of the display region DA except for the side of the display region DA. The second power supply electrode layer ELVSS may be electrically connected to the pixel structure PX, and may provide a second power supply voltage to the pixel structure PX. According to an embodiment, the second power supply electrode layer ELVSS may be electrically connected to some of the first pad electrodes disposed in the first pad region PDA1 through a first connection line CL1.

The gate driving member GDV may be adjacent to at least one side of the display region DA. The gate driving member GDV may be electrically connected to the scan line SL and may provide the scan signal to the scan line SL. According to an embodiment, the gate driving member GDV may be electrically connected to some of the first pad electrodes disposed in the first pad region PDA1 through a second connection line CL2.

The driving chip DC may be disposed between the first power supply electrode layer ELVDD and the second pad region PDA2. According to an embodiment, the driving chip DC may be omitted. The wire region LA may include only the first wire region LA1 and the second wire region LA2, the second wire region LA2 may extend from the first wire region LA1 to the second pad region PDA2, and the wires disposed in the second wire region LA2 may electrically contact the wires disposed in the first wire region LA1 and the second pad electrodes disposed in the second pad region PDA2.

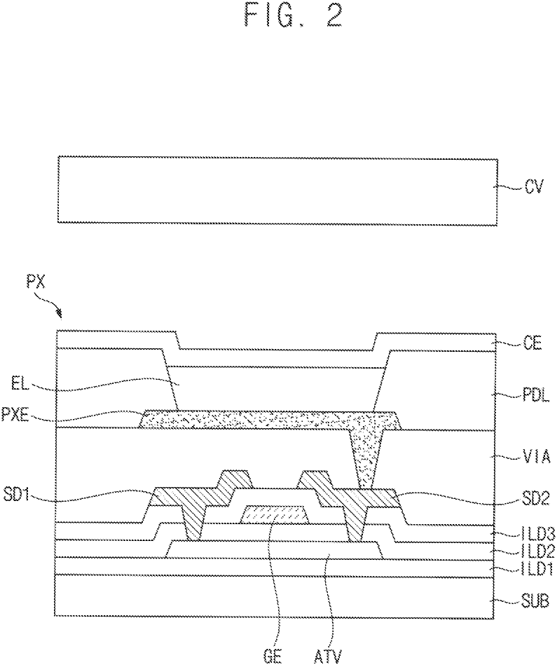

A sealing region SA surrounding the display region DA may be located at a periphery of the display region DA. The sealing region SA will be described in detail below with reference to FIG. 2.

A portion of the protective layer PLa may overlap a boundary between the first wire region LA1 and the second wire region LA2. According to an embodiment, another portion of the protective layer PLa may partially overlap a region in which the sealing region SA overlaps the first wire region LA1.

The protective layer PLa may be electrically insulated (or electrically disconnected) from the wires disposed in the first wire region LA1 and the wires disposed in the second wire region LA2. In detail, the protective layer PLa may be disposed on the wires disposed in the first wire region LA1 and the wires disposed in the second wire region LA2, and at least one insulating layer may be disposed between the protective layer PLa and the wires disposed in the first wire region LA1 and between the protective layer PLa and the wires disposed in the second wire region LA2.

In some embodiments, the protective layer PLa may be electrically connected to the second power supply electrode layer ELVSS, and the protective layer PLa may not be electrically coupled to the wires disposed in the first wire region LA1 and the wires disposed in the second wire region LA2. For example, the protective layer PLa may be electrically connected to the first connection line CL1 by a floating line FLa.

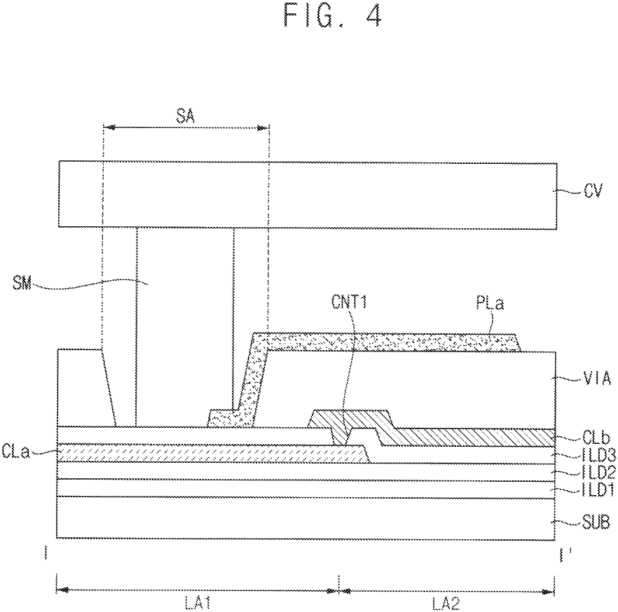

According to an embodiment, the protective layer PLa and the first power supply electrode layer ELVDD may include a same material, and may be disposed on a same layer. The protective layer PLa may be electrically insulated from the first power supply electrode layer ELVDD. The protective layer PLa will be described in detail below with reference to FIGS. 3 and 4.

FIG. 2 is a schematic sectional view illustrating a pixel structure included in the display device of FIG. 1.

Referring to FIG. 2, the pixel structure PX may include a first insulating layer ILD1, a second insulating layer ILD2, an inorganic insulating layer ILD3, a semiconductor layer ATV, a gate electrode GE, first and second source-drain electrodes SD1 and SD2, an organic insulating layer VIA, a pixel electrode layer PXE, a pixel defining layer PDL, a light emitting material EL, and a common electrode layer CE.

The first insulating layer ILD1 may be disposed on the substrate SUB. The first insulating layer ILD1 may include an inorganic insulating material. The first insulating layer ILD1 may block impurities from being introduced from the substrate SUB.

The semiconductor layer ATV may be disposed on the first insulating layer ILD1. The semiconductor layer ATV may include a semiconductor material. For example, the semiconductor layer ATV may include an oxide semiconductor and/or a silicon semiconductor. However, the embodiments are not limited thereto.

The second insulating layer ILD2 may be disposed on the first insulating layer ILD1, and may cover the semiconductor layer ATV. The second insulating layer ILD2 may include an inorganic insulating material. The second insulating layer ILD2 may electrically insulate the gate electrode GE, which will be described below, from the semiconductor layer ATV.

The gate electrode GE may be disposed on the second insulating layer ILD2. The gate electrode GE may overlap at least a portion of the semiconductor layer ATV. According to an embodiment, the gate electrode GE may be electrically connected to the scan line SL described with reference to FIG. 1, and may receive the scan signal from the scan line SL. In case that the scan signal is provided to the gate electrode GE, electrical conductivity of the semiconductor layer ATV may be relatively increased.

The inorganic insulating layer ILD3 may be disposed on the second insulating layer ILD2, and may cover the gate electrode GE. The inorganic insulating layer ILD3 may electrically insulate the gate electrode GE from the first and second source-drain electrodes SD1 and SD2.

The first and second source-drain electrodes SD1 and SD2 may be disposed on the inorganic insulating layer ILD3. Each of the first and second source-drain electrodes SD1 and SD2 may electrically contact the semiconductor layer ATV through a through-hole formed through the second insulating layer ILD2 and the inorganic insulating layer ILD3 to expose a top surface of the semiconductor layer ATV. According to an embodiment, the first source-drain electrode SD1 may be electrically connected to at least one of the first power supply voltage line PL1 and the data line DL, which are described with reference to FIG. 1.

The organic insulating layer VIA may be disposed on the inorganic insulating layer ILD3, and may cover the first and second source-drain electrodes SD1 and SD2.

The pixel electrode layer PXE may be disposed on the organic insulating layer VIA. The pixel electrode layer PXE may include a conductive material. The pixel electrode layer PXE may electrically contact the second source-drain electrode SD2 through a through-hole formed through the organic insulating layer VIA to expose a top surface of the second source-drain electrode SD2. According to an embodiment, the pixel electrode layer PXE may be referred to as an anode electrode.

The pixel defining layer PDL may be disposed on the organic insulating layer VIA and the pixel electrode layer PXE. The pixel defining layer PDL may define a pixel opening that exposes at least a portion of the pixel electrode layer PXE.

The light emitting material EL may be disposed on the pixel electrode layer PXE within the pixel opening. According to an embodiment, the light emitting material EL may include an organic light emitting material.

The common electrode layer CE may cover the pixel defining layer PDL and the light emitting material EL. The common electrode layer CE may be electrically connected to the second power supply electrode layer ELVSS, and may receive the second power supply voltage from the second power supply electrode layer ELVSS. According to an embodiment, the common electrode layer CE may be referred to as a cathode electrode.

Referring again to FIGS. 1 and 2, each of the first and second insulating layers ILD1 and ILD2, the inorganic insulating layer ILD3, and the organic insulating layer VIA may be disposed over the whole substrate SUB. For example, each of the first and second insulating layers ILD1 and ILD2, the inorganic insulating layer ILD3, and the organic insulating layer VIA may be disposed on the substrate SUB in the display region DA and the wire region LA, and may be disposed on the substrate SUB in a portion of the peripheral region PA.

According to an embodiment, the display device DDa may include the sealing region SA. The sealing region SA may be defined as a region in which a sealing opening that opens (or penetrates) the organic insulating layer VIA is formed.

In the sealing region SA, a sealing member (SM of FIG. 4) may be disposed in the sealing opening. A cover member CV supported by the sealing member SM may be disposed on the sealing member (SM of FIG. 4). According to an embodiment, the sealing region SA may surround the display region DA, so that the display region DA may be sealed by the sealing member SM and the cover member CV.

FIG. 3 is a schematic enlarged plan view illustrating region A of FIG. 1. FIG. 4 is a schematic sectional view taken along line I-I′ of FIG. 3.

Referring to FIGS. 1 to 4, a first wire part including first wires CLa may be disposed in the first wire region LA1, and a second wire part including second wires CLb may be disposed in the second wire region LA2.

The first wires CLa and the gate electrode GE may include a same material, and may be disposed on a same layer. In other words, the first wires CLa may be disposed on the second insulating layer ILD2.

The second wires CLb and the first and second source-drain electrodes SD1 and SD2 may include a same material, and may be disposed on a same layer. In other words, the second wires CLb may be disposed on the inorganic insulating layer ILD3.

The second wires CLb may electrically contact the first wires CLa through first through-holes CNT1 formed through the inorganic insulating layer ILD3 to expose portions of the first wires CLa, respectively. The first through-holes CNT1 may be arranged along the boundary between the first wire region LA1 and the second wire region LA2.

According to an embodiment, the first wires CLa may include a material having a first resistivity, and the second wires CLb may include a material having a second resistivity that is lower than the first resistivity. For example, the first wires CLa may include molybdenum, and the second wires CLb may include aluminum. According to the disclosure, since the first wires CLa electrically contact the second wires CLb, even in case that a wire width of each of the first wires CLa and the second wires CLb becomes relatively small, a total resistance of the first wires CLa and the second wires CLb electrically contacting the first wires CLa may become relatively low, and thus widths of the first wire region LA1 and the second wire region LA2 in the first direction DR1 may become relatively small. As a result, an area of a bezel of the display device DDa may become relatively small.

According to an embodiment, the second wire region LA2 may be spaced apart from the sealing region SA in the first direction DR1 in a plan view, and a portion of the first wire region LA1 may overlap a portion of the sealing region SA in a plan view. In case that the sealing region SA overlaps the second wire region LA2 in a plan view, when the sealing opening is formed by removing a portion of the organic insulating layer VIA, the second wires CLb disposed in the second wire region LA2 may be damaged. For example, when the sealing opening is formed by removing the portion of the organic insulating layer VIA by a dry etching scheme, the second wires CLb disposed in the second wire region LA2 overlapping the sealing region SA in a plan view may be damaged. Therefore, according to the disclosure, in order to prevent the second wires CLb from being damaged, the sealing region SA may be spaced apart from the second wire region LA2 in a plan view.

The protective layer PLa and the pixel electrode layer PXE may include a same material, and may be disposed on a same layer. In other words, the protective layer PLa may be disposed on the organic insulating layer VIA.

The portion of the protective layer PLa may overlap the first through-hole CNT1. In other words, the portion of the protective layer PLa may overlap the boundary between the first wire region LA1 and the second wire region LA2.

In case that the protective layer PLa does not exist, impurities may be introduced into the first through-hole CNT1 through the organic insulating layer VIA. As a result, the first wires CLa and the second wires CLb, which are adjacent to the first through-hole CNT1, may be damaged by the impurities. According to the disclosure, the portion of the protective layer PLa may overlap the first through-hole CNT1, and the protective layer PLa may block the impurities from being introduced into the first through-hole CNT1 through the organic insulating layer VIA so as to prevent the first wires CLa and the second wires CLb from being damaged by the impurities.

According to an embodiment, the protective layer PLa may cover a portion of a top surface of the inorganic insulating layer ILD3 exposed by the sealing opening in a region where the first wire region LA1 overlaps the sealing region SA. In other words, the protective layer PLA may extend from a top surface of the organic insulating layer VIA overlapping the first through-hole CNT1 along a side surface of the sealing opening that is adjacent to the first through-hole CNT1 onto the portion of the top surface of the inorganic insulating layer ILD3 exposed by the sealing opening. Accordingly, the protective layer PLa may block the impurities from being introduced through the side surface of the sealing opening that is adjacent to the first through-hole CNT1.

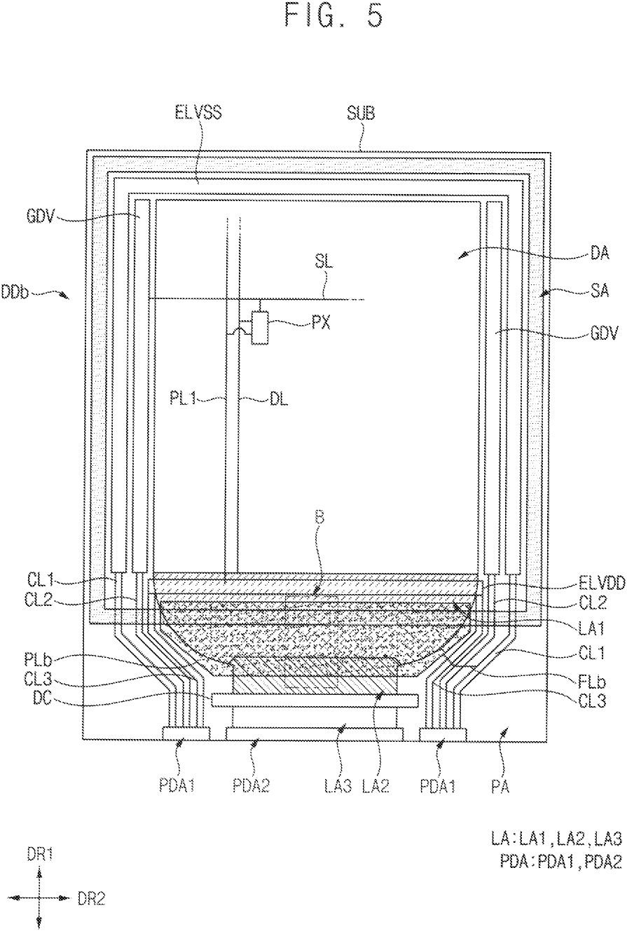

FIG. 5 is a schematic plan view illustrating a display device according to another embodiment of the disclosure.

A display device DDb according to another embodiment of the disclosure shown in FIG. 5 may be distinguishable from the display device DDa according to an embodiment of the disclosure described with reference to FIGS. 1 to 4 at least in a shape of a protective layer PLb in a plan view. Repetitive descriptions thereof will be omitted below.

Referring to FIG. 5, a portion of the protective layer PLb may overlap the boundary between the first wire region LA1 and the second wire region LA2. Another portion of the protective layer PLb may overlap the region where the first wire region LA1 overlaps the sealing region SA. The protective layer PLb may be electrically insulated from the wires disposed in the first wire region LA1 and the wires disposed in the second wire region LA2.

In some embodiments, the protective layer PLb may be electrically connected to the second power supply electrode layer ELVSS. For example, the protective layer PLb may be electrically connected to the first connection line CL1 through a floating line FLb.

According to an embodiment, the protective layer PLb and the first power supply electrode layer ELVDD may include a same material, and may be disposed on a same layer. The protective layer PLb may be electrically insulated from the first power supply electrode layer ELVDD.

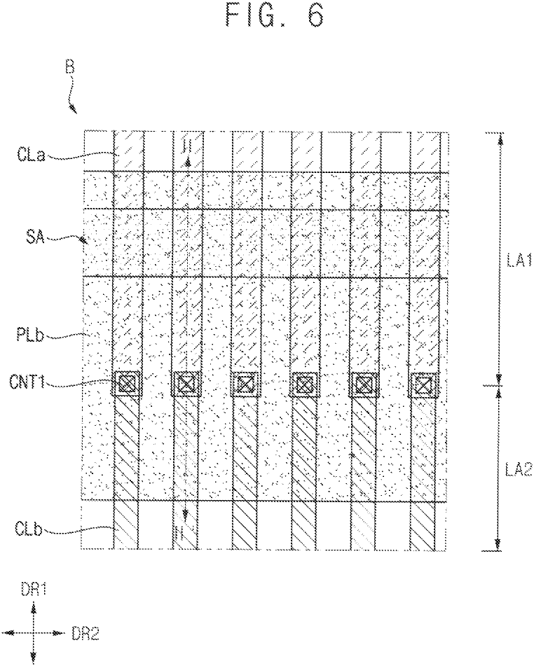

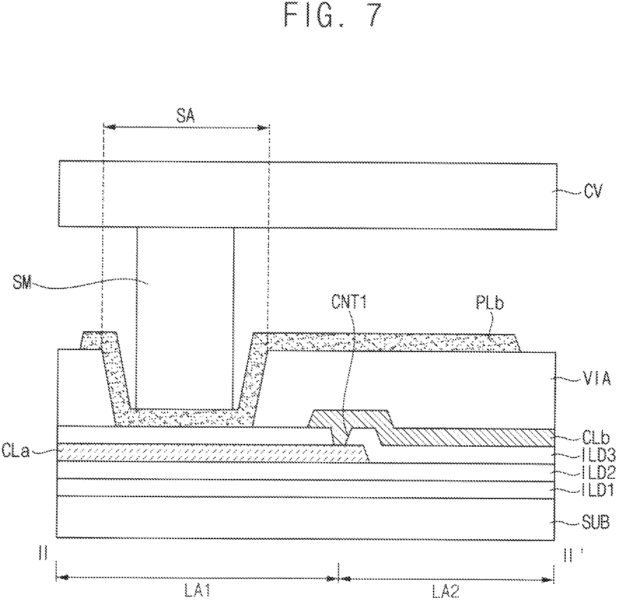

FIG. 6 is a schematic enlarged plan view illustrating region B of FIG. 5. FIG. 7 is a schematic sectional view taken along line I-II′ of FIG. 6.

Referring to FIGS. 5 to 7, the portion of the protective layer PLb may overlap the first through-hole CNT1. Accordingly, the protective layer PLb may block impurities from being introduced into the first through-hole CNT1 through the organic insulating layer VIA so as to prevent the first wires CLa and the second wires CLb from being damaged by the impurities.

The protective layer PLb may cover side surfaces of the sealing opening and the entire top surface of the inorganic insulating layer ILD3 exposed by the sealing opening in the region where the first wire region LA1 overlaps the sealing region SA.

According to an experiment, the first wires CLa overlapping the sealing region SA were vulnerable to damage. According to the disclosure, the protective layer PLb may cover the side surfaces of the sealing opening and the entire top surface of the inorganic insulating layer ILD3 exposed by the sealing opening, so that the protective layer PLb may prevent the first wires CLa overlapping the sealing region SA from being damaged. The protective layer PLb may block the impurities from being introduced through the side surfaces of the sealing opening.

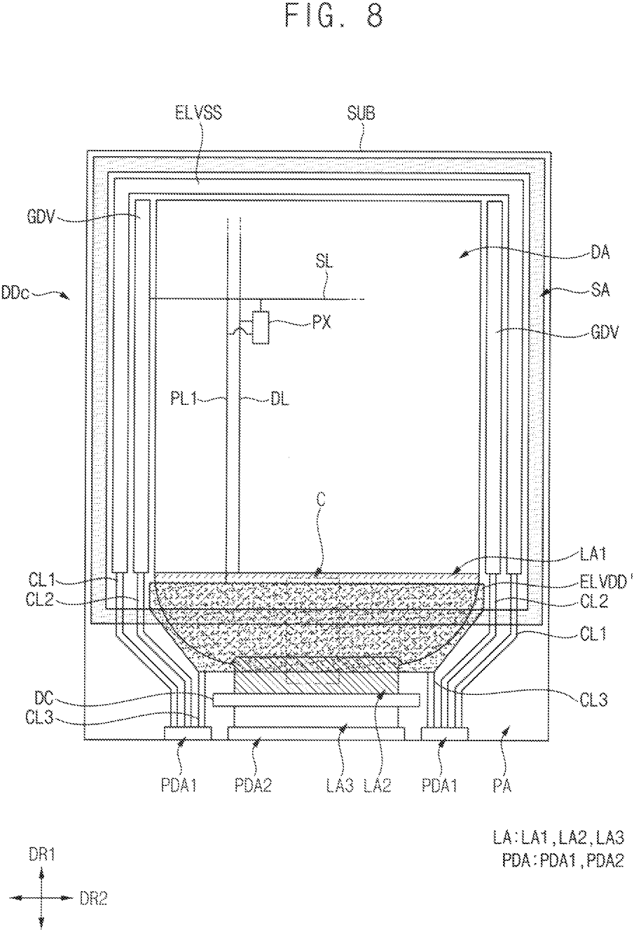

FIG. 8 is a schematic plan view illustrating a display device according to still another embodiment of the disclosure.

A display device DDc according to still another embodiment of the disclosure shown in FIG. 8 may be distinguishable from the display device DDa according to an embodiment of the disclosure described with reference to FIGS. 1 to 4 at least in a shape of a first power supply electrode layer ELVDD’ and an inclusion state of the protective layer PLa. Repetitive descriptions thereof will be omitted below.

Referring to FIG. 8, unlike the display device DDa according to an embodiment of the disclosure, the display device DDc according to still another embodiment of the disclosure does not include the protective layer PLa.

A portion of the first power supply electrode layer ELVDD’ may overlap the boundary between the first wire region LA1 and the second wire region LA2. Another portion of the first power supply electrode layer ELVDD’ may overlap the region where the first wire region LA1 overlaps the sealing region SA.

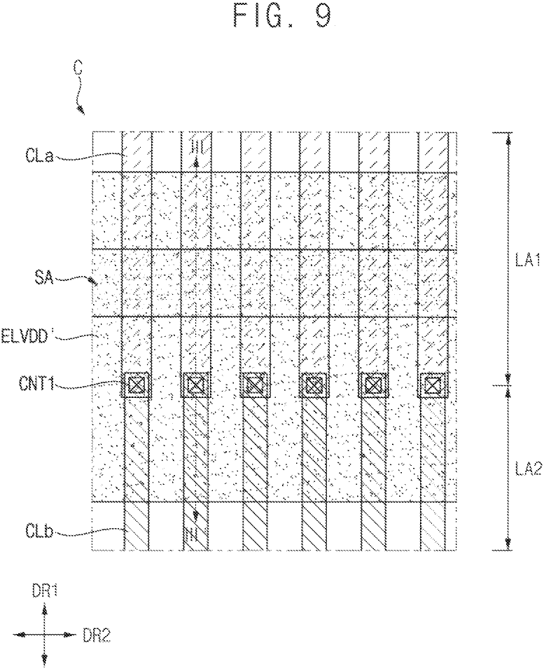

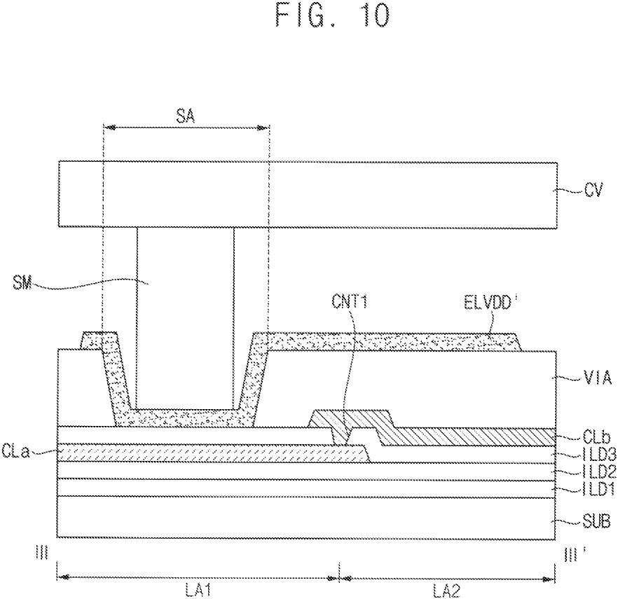

FIG. 9 is a schematic enlarged plan view illustrating region C of FIG. 8. FIG. 10 is a schematic sectional view taken along line III-III’ of FIG. 9.

Referring to FIGS. 8 to 10, the portion of the first power supply electrode layer ELVDD’ may overlap the first through-hole CNT1. Accordingly, the first power supply electrode layer ELVDD’ may block impurities from being introduced into the first through-hole CNT1 through the organic insulating layer VIA so as to prevent the first wires CLa and the second wires CLb from being damaged by the impurities.

The first power supply electrode layer ELVDD’ may cover side surfaces of the sealing opening and the entire top surface of the inorganic insulating layer ILD3 exposed by the sealing opening in the region where the first wire region LA1 overlaps the sealing region SA. Accordingly, the first power supply electrode layer ELVDD’ may prevent the first wires CLa overlapping the sealing region SA from being damaged, and may block the impurities from being introduced through the side surfaces of the sealing opening.

Although embodiments of the present disclosure have been described above, it will be understood by those of ordinary skill in the art that various changes and modifications can be made to the present disclosure without departing from the idea and scope of the disclosure.

The disclosure may be applied to various display devices. For example, the disclosure may be applied to various display devices such as display devices for vehicles, ships, and aircraft, portable communication devices, display devices for exhibition or information transmission, and medical display devices.

What is claimed is:

1. A display device comprising:
a display region;
a first wire region extending in a direction from a side of the display region;
a second wire region extending in the direction from the first wire region;
a peripheral region surrounding the display region, the first wire region, and the second wire region;
a pixel structure disposed on a substrate in the display region;
a first wire part disposed on the substrate in the first wire region, and including first wires electrically connected to the pixel structure;
an inorganic insulating layer covering the first wire part;
a second wire part disposed on the inorganic insulating layer in the second wire region, and including second wires electrically contacting the first wires through first through-holes formed through the inorganic insulating layer and arranged along a boundary between the first wire region and the second wire region, respectively;
an organic insulating layer covering the second wire part; and
a protective layer disposed on the organic insulating layer, and at least partially overlapping the first through-holes in a plan view.

2. The display device of claim 1, further comprising:
a sealing region defined by a sealing opening that penetrates the organic insulating layer, and surrounding the display region.

3. The display device of claim 2, wherein
the second wire region is spaced apart from the sealing region in a plan view, and
a portion of the first wire region overlaps a portion of the sealing region in a plan view.

4. The display device of claim 3, wherein the protective layer covers a portion of a top surface of the inorganic insulating layer exposed by the sealing opening in a region where the portion of the first wire region overlaps the portion of the sealing region in a plan view.

5. The display device of claim 4, wherein the protective layer further covers the sealing opening and the entire top surface of the inorganic insulating layer exposed by the sealing opening in the region where the portion of the first wire region overlaps the portion of the sealing region in a plan view.

6. The display device of claim 2, further comprising:
a sealing member disposed within the sealing opening; and
a cover member supported by the sealing member.

7. The display device of claim 1, wherein the pixel structure includes:
a semiconductor layer disposed on the substrate;
a gate electrode disposed on the semiconductor layer and at least partially overlapping a portion of the semiconductor layer in a plan view, the gate electrode and the first wire part including a same material;
the inorganic insulating layer covering the gate electrode;
a source-drain electrode disposed on the inorganic insulating layer and electrically contacting another portion of the semiconductor layer, the source-drain electrode and the second wire part including a same material;
the organic insulating layer covering the source-drain electrode; and
a pixel electrode layer disposed on the organic insulating layer and electrically contacting the source-drain electrode, the pixel electrode layer and the protective layer including a same material.

8. The display device of claim 1, wherein
the first wire part includes a material having a first resistivity, and
the second wire part includes a material having a second resistivity that is lower than the first resistivity.

9. The display device of claim 1, further comprising:
a first power supply electrode layer disposed on the substrate and adjacent to the side of the display region, and receiving a first power supply voltage; and
a second power supply electrode layer disposed on the substrate in the peripheral region, and receiving a second power supply voltage.

10. The display device of claim 9, wherein the first power supply electrode layer and the protective layer include a same material.

11. The display device of claim 9, wherein the first power supply electrode layer is electrically insulated from the protective layer.

12. The display device of claim 9, wherein the protective layer is electrically connected to the second power supply electrode layer.

13. A display device comprising:
a display region;
a first wire region extending from a side of the display region;
a second wire region extending from the first wire region;
a peripheral region surrounding the display region, the first wire region, and the second wire region, and including a pad region in which pad electrodes are disposed;
a pixel structure disposed on a substrate in the display region;
a first wire part disposed on the substrate in the first wire region, and including first wires electrically connected to the pixel structure;
an inorganic insulating layer covering the first wire part;
a second wire part disposed on the inorganic insulating layer in the second wire region, and including second wires electrically contacting the first wires through first through-holes formed through the inorganic insulating layer and arranged along a boundary between the first wire region and the second wire region, respectively;
an organic insulating layer covering the second wire part; and
a first power supply electrode layer disposed on the organic insulating layer, electrically connected to at least one of the pad electrodes, and at least partially overlapping the first through-hole in a plan view.

14. The display device of claim 13, further comprising:
a sealing region defined by a sealing opening that penetrates the organic insulating layer, and surrounding the display region.

15. The display device of claim 14, wherein
the second wire region is spaced apart from the sealing region in a plan view, and
a portion of the first wire region overlaps a portion of the sealing region in a plan view.

16. The display device of claim 15, wherein the first power supply electrode layer covers the sealing opening and an entire top surface of the inorganic insulating layer exposed by the sealing opening in a region where the portion of the first wire region overlaps the portion of the sealing region in a plan view.

17. The display device of claim 14, further comprising:
a sealing member disposed within the sealing opening; and
a cover member supported by the sealing member.

18. The display device of claim 13, wherein the pixel structure includes:
a semiconductor layer disposed on the substrate;
a gate electrode disposed on the semiconductor layer and at least partially overlapping one portion of the semiconductor layer in a plan view, the gate electrode and the first wire part including a same material;
the inorganic insulating layer covering the gate electrode;
a source-drain electrode disposed on the inorganic insulating layer and electrically contacting another portion of the semiconductor layer, the source-drain electrode and the second wire part including a same material;
the organic insulating layer covering the source-drain electrode; and
a pixel electrode layer disposed on the organic insulating layer and electrically contacting the source-drain electrode, the pixel electrode layer and the first power supply electrode layer including a same material.

19. The display device of claim 13, wherein
the first wire part includes a material having a first resistivity, and
the second wire part includes a material having a second resistivity that is lower than the first resistivity.

20. The display device of claim 13, further comprising:
a second power supply electrode layer disposed on the substrate in the peripheral region, wherein
the first power supply electrode layer receives a first power supply voltage, and
the second power supply electrode layer receives a second power supply voltage.
